(19) United States
(12) Patent Application Publication
(10) Pub. No.: US 2010/0052732 A1
(43) Pub. Date: Mar. 4, 2010

(54) FREQUENCY DETECTION CIRCUIT

(75) Inventor: Takashi TOKANO, Oota-City (JP)

Correspondence Address: WATCHSTONE P+D, PLLC, 1250 CONNECTICUT AVENUE, N.W., SUITE 700, WASHINGTON, DC, 20036-2657, US

(73) Assignees: SANYO ELECTRIC CO., LTD.; SANYO SEMICONDUCTOR CO., LTD.

(21) Appl. No.: 12/509,038

(22) Filed: Jul. 24, 2009

(30) Foreign Application Priority Data
Aug. 6, 2008 (JP) 2008-203280

(51) Int. Cl. H03K 5/26

(52) U.S. Cl. 327/47

(57) ABSTRACT

In some preferred embodiments, a switched capacitor circuit configured to change its equivalent resistance depending on the frequency of an input clock signal and a resistor element are connected in series. A power source voltage is divided by the equivalent resistance of the switched capacitor circuit and the resistance of the resistor element, and the divided voltage is inputted to a Schmitt circuit. The Schmitt circuit outputs a high-level signal when the inputted divided voltage is higher than a threshold voltage and a low-level signal when the inputted divided voltage is lower than a threshold voltage. Thus, depending on the frequency of the input clock signal, a high-level signal or a low-level signal is outputted.

This application claims priority under 35 U.S.C. §119 to Japanese Patent Application No. 2008-203280 filed on Aug. 6, 2008, the entire disclosure of which is incorporated herein by reference in its entirety.

### BACKGROUND OF THE INVENTION

1. Field of the Invention

The present invention relates to a frequency detection circuit. More specifically it relates to a frequency detection circuit preferably for use in, e.g., a sleeve circuit for LSIs with no standby terminal and configured to output a high-level signal or a low-level signal when a frequency of an input clock signal is higher or lower than a pre-set frequency, respectively.

2. Description of the Related Art

The following description sets forth the inventor's knowledge of related art and problems therein and should not be construed as an admission of knowledge in the prior art.

For example, in some sleeve circuits for LSIs with no standby terminal, the circuit is configured to output a low-level signal when the frequency of an input clock signal is lower than a predetermined low frequency (e.g., 1 kHz) and output a high-level signal when the frequency of the input clock signal is higher than a predetermined high frequency (e.g., 2 MHz) to thereby perform a standby control of an electronic circuit. As a conventional method for detecting the frequency of such input clock signal, it is known to use a F-V converter (Frequency to Voltage Converter) and compare the output of the converter.

As a circuit for detecting a frequency using a conventional F-V converter, a circuit using an operation amplifier is known.

The circuit for detecting a frequency using a conventional F-V converter is equipped with an operation amplifier as explained above, and therefore there are drawbacks that the circuit is complicated in structure, large in electric power consumption, and large in size.

The description herein of advantages and disadvantages of various features, embodiments, methods, and apparatus disclosed in other publications is in no way intended to limit the present invention. For example, certain features of the preferred embodiments of the invention may be capable of overcoming certain disadvantages and/or providing certain advantages, such as, e.g., disadvantages and/or advantages discussed herein, while retaining some or all of the features, embodiments, methods, and apparatus disclosed therein.

### SUMMARY OF THE INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide a frequency detection circuit capable of attaining miniaturization and power saving and also capable of assuredly detecting a frequency of an input clock signal.

According to a first aspect of the present invention, a frequency detection circuit, comprises:

a switched capacitor circuit having one end to which a power source voltage is applied, the switched capacitor circuit being configured to change its equivalent resistance depending on a frequency of an input clock signal;

a resistor element having one end to which the other end of the switched capacitor circuit is connected and the other end grounded; and

a divided voltage detection circuit configured to detect a divided voltage of the power source voltage divided by the switched capacitor circuit and the resistor element and output a high-level signal when the divided voltage is higher than a threshold voltage and a low-level signal when the divided voltage is lower than the threshold voltage.

In the aforementioned frequency detection circuit, it is preferable to use a Schmitt circuit as the divided voltage detection circuit to prevent output fluctuations when the frequency of the input clock signal to be detected is near the threshold frequency.

In some preferred embodiments, it is preferable to further comprise a smoothing capacitor with one end connected to a connection point of the switched capacitor circuit and the resistor element and the other end grounded.

In some preferred embodiments, it is preferable to further comprise a clock generator configured to input the input clock signal, create two kinds of control signals reverse in phase and having non-overlap durations from the input clock signal, and output the control signals to the switched capacitor circuit.

In some preferred embodiments, it is preferable that the switched capacitor circuit includes:

a first MOS transistor having a source terminal to which the power source voltage is applied and a gate terminal to which one of the two kinds of control signals is inputted;

a second MOS transistor having a source terminal to which a drain terminal of the first MOS transistor is connected and a gate terminal to which the other of the two kinds of control signals is inputted; and

a capacitor having one end to which a connection point of the drain terminal of the first MOS transistor and the source terminal of the second MOS transistor is connected and the other end grounded.

According to a second aspect of the present invention, a frequency detection circuit comprises:

a switched capacitor circuit unit including a switched capacitor circuit, wherein the switched capacitor circuit is configured to change its equivalent resistance depending on a frequency of an input clock signal inputted to the switched capacitor circuit unit;

a resistor element connected between the switched capacitor circuit and a ground terminal so as to divide a reference voltage by the equivalent resistance of the switched capacitor circuit and a resistance of the resistor element;

a smoothing capacitor connected to the resistor element in parallel; and

a Schmitt circuit configured to input a divided voltage of the reference voltage divided by the equivalent resistance of the switched capacitor circuit and the resistance of the resistor element and output a high-level signal or a low-level signal depending on the inputted divided voltage, whereby the Schmitt circuit outputs the high-level signal when the frequency of the input clock signal is higher than a predetermined threshold frequency and outputs the low-level signal when the frequency of the input clock signal is lower than a predetermined threshold frequency.

In the aforementioned frequency detection circuit, it is preferable that the switched capacitor circuit unit includes:

a clock generator configured to input the input clock signal and create two kinds of control signals reverse in phase; and
the switched capacitor circuit which is controlled so that the equivalent resistance changes depending on the frequency of the input clock signal.

The switched capacitor circuit preferably includes:

a first MOS transistor having a source terminal to which the reference voltage is applied and a gate terminal to which one of the two kinds of control signals is inputted;

a second MOS transistor having a source terminal to which a drain terminal of the first MOS transistor is connected and a gate terminal to which the other of the two kinds of control signals is inputted; and

a capacitor having one end to which a connection point of the drain terminal of the first MOS transistor and the source terminal of the second MOS transistor is connected and the other end grounded.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by way of example, and not limitation, in the accompanying figures, in which:

FIG. 1 is a schematic block diagram of a frequency detection circuit according to an embodiment of the present invention;

FIG. 2A is a waveform chart of an input clock signal having a high frequency;

FIG. 2B is another waveform chart of an input clock signal having a low frequency;

FIG. 3A is a waveform chart of input terminal signals of a Schmitt circuit;

FIG. 3B is a waveform chart of output terminal signals of the Schmitt circuit;

FIG. 4 is a principle explanatory diagram of a switched capacitor circuit.

FIG. 5 is a waveform chart of output signals (control signals) of a clock generator;

FIG. 6 is a concrete circuit diagram of a frequency detection circuit according to an embodiment of the present invention;

FIG. 7 is a waveform chart showing an input clock signal, a divided voltage potential, and an output signal of the frequency detection circuit according to the embodiment in the case where the frequency of the input signal is 200 kHz;

FIG. 8 is a waveform chart showing an input clock signal, a divided voltage potential, and an output signal of the frequency detection circuit according to the embodiment in the case where the frequency of the input signal is 1 MHz;

FIG. 9 is a waveform chart showing an input clock signal, a divided voltage potential, and an output signal of the frequency detection circuit according to the embodiment in the case where the frequency of the input signal is 460 kHz and the threshold frequency of the Schmitt circuit is 470 kHz; and

FIG. 10 is a waveform chart showing an input clock signal, a divided voltage potential, and an output signal of the frequency detection circuit according to the embodiment in the case where the frequency of the input signal is 470 kHz and the threshold frequency of the Schmitt circuit is 470 kHz.

### DETAILED DESCRIPTION OF THE PREFERRED EMBODIMENTS

In the following paragraphs, some preferred embodiments of the invention will be described by way of example and not limitation. It should be understood based on this disclosure that various other modifications can be made by those in the art based on these illustrated embodiments.

Hereinafter, an embodiment of the present invention will be explained with reference to the attached drawings.

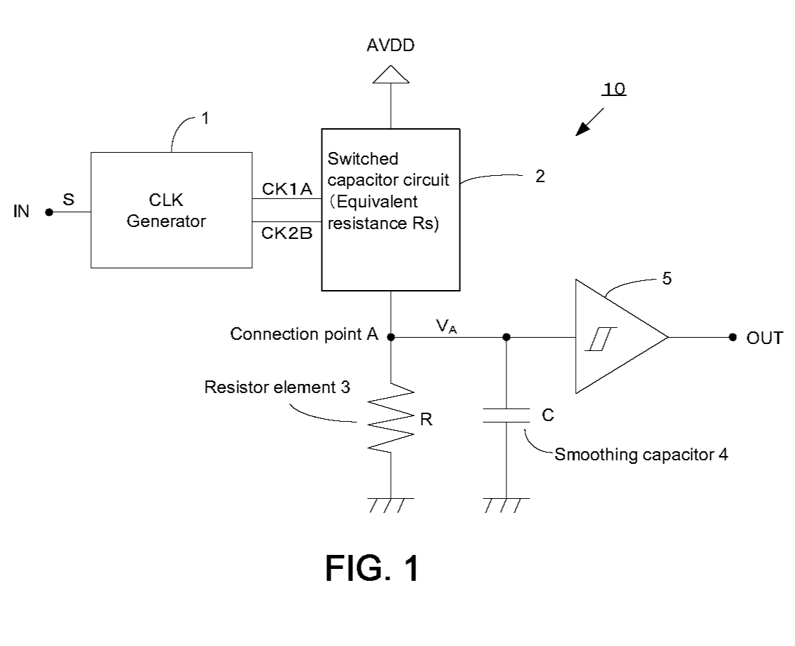

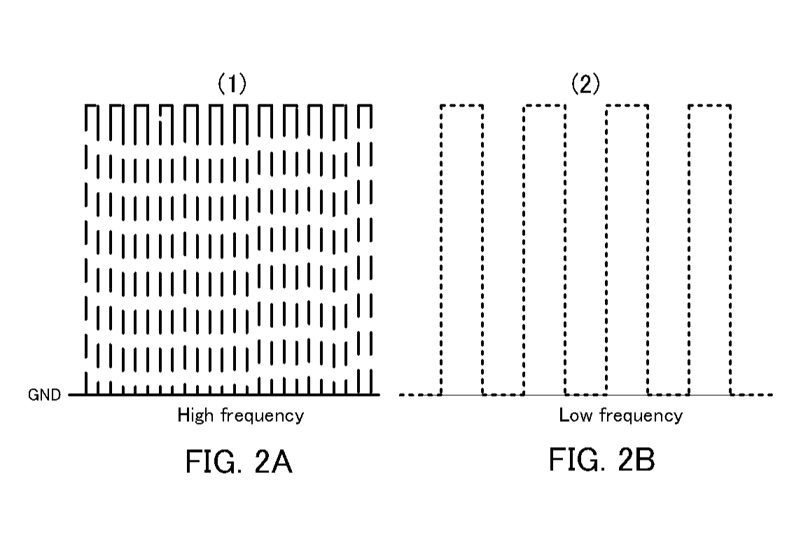

FIG. 1 shows a schematic block diagram of a frequency detection circuit 10 according to an embodiment of the present invention. This frequency detection circuit 10 is comprised of a clock generator 1, a switched capacitor circuit 2, a resistor element 3, a capacitor 4, and a Schmitt circuit 5. It should be noted that the present invention is not limited to this embodiment and that the embodiment can be arbitrarily modified within the scope of the present invention.

One end of the switched capacitor circuit 2 is connected to a power supply terminal and a power supply voltage AVDD as a reference voltage is applied to the one end. The other end of the switched capacitor circuit 2 is connected to one end of the resistor element 3. The other end of the resistor element 3 is grounded. Thus, the equivalent resistance Rs of the switched capacitor circuit 2 and the resistance R of the resistor element 3 are connected in series, so that the power source voltage AVDD is divided by the equivalent resistance Rs of the switched capacitor circuit 2 and the resistance R of the resistor element 3.

A clock generator 1 is connected to the switched capacitor circuit 2. This clock generator 1 is configured to create predetermined control signals CK1A and CK2B reverse in phase and having non-overlap durations from a clock signal S inputted from the input terminal IN and output both the control signals CK1A and CK2B to the switched capacitor circuit 2.

Connected to both ends of the resistor element 3 is a smoothing capacitor 4. This capacitor 4 is configured to smooth the divided voltage V_{A} appeared at both ends of the resistor element 3.

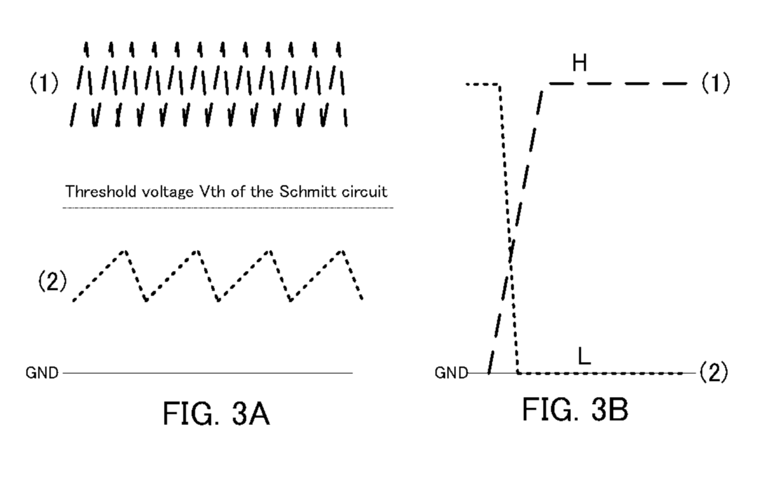

An input terminal of the Schmitt circuit 5 is connected to the connection portion A where the switched capacitor circuit 2 and the resistor element 3 are connected, so that the divided voltage V_{A} is applied to the Schmitt circuit 5. As shown in FIGS. 3A and 3B, when the divided voltage V_{A} is higher than the threshold voltage Vth of the Schmitt circuit 5 (see the voltage (1) in FIG. 3A), the Schmitt circuit 5 outputs a high-level signal H (see the signal (1) in FIG. 3B). On the other hand, when the divided voltage V_{A} is lower than the threshold voltage Vth of the Schmitt circuit 5 (see the voltage (2) in FIG. 3A), the Schmitt circuit 5 outputs a low-level signal L (see the signal (2) in FIG. 3B).

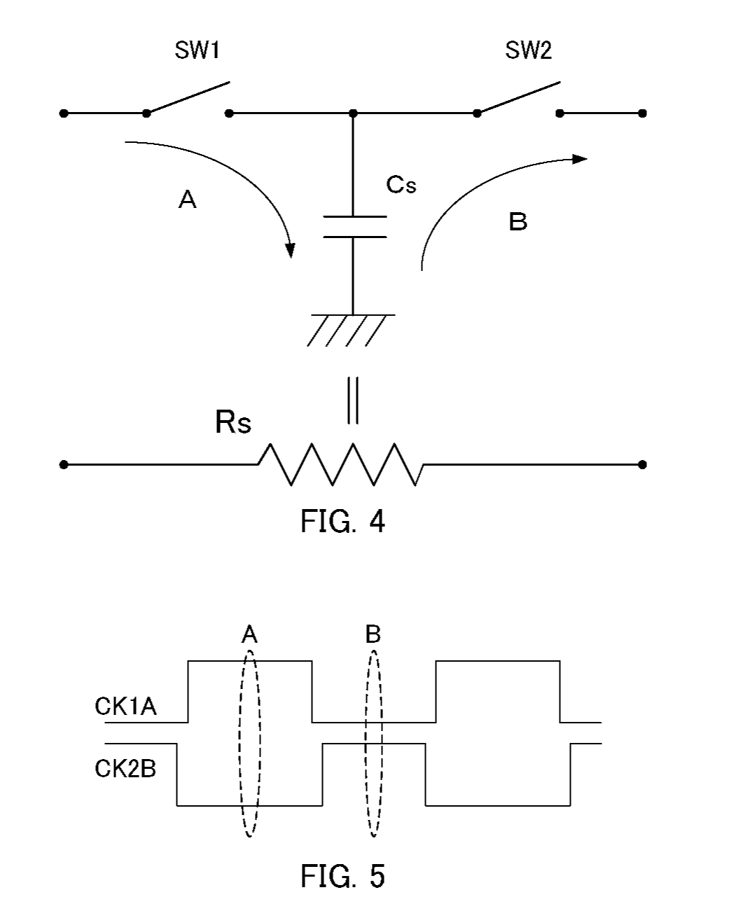

The switched capacitor circuit 2 is an electronic circuit constituted by a capacitor and electronic switches (MOS transistors) and configured to realize a pseudo resistor by control signals. The circuit 2 does not consume electric power theoretically. FIG. 4 shows a principle diagram of a switched capacitor circuit. As shown in FIG. 4, in a switched capacitor circuit, an electronic switch SW1 (e.g., MOS transistor) is connected the charging side (input side or left side) of a capacitor Cs, and an electronic switch SW2 (e.g., MOS transistor) is connected to the discharging side (output side or right side) of the capacitor Cs. The On/Off operation of the charging side switch SW1 and that of the discharging side switch SW2 are controlled by control signals CK1A and CK2B which are reverse in phase and have non-overlap durations as shown in FIG. 5. For example, at the timing A shown in FIG. 5, the charging side switch SW1 is turned on and the discharging side switch SW2 is turned off, which causes charging of the capacitor Cs. On the other hand, at the timing B shown in FIG. 5, the charging side switch SW1 is turned off and the discharging side switch SW2 is turned on, which causes discharging of the capacitor Cs. When the switching frequency or the frequency of the input clock signal is “f,” the equivalent resistance Rs of the switched capacitor circuit 2 can be calculated by the equation of Rs=1/fCs. As will be understood from this equation, the switched capacitor circuit 2 functions as a resistor which creates a resistance Rs corresponding to the frequency f of the input clock signal S.

In the frequency detection circuit 10 shown in FIG. 1, when a clock signal S having a predetermined frequency is inputted to the clock generator 1, the clock generator 1 generates control signals CK1A and CK2B which are reverse in phase and have non-overlap durations from the inputted clock signal S. These control signals CK1A and CK2B are inputted into the switched capacitor circuit 2. As a result, the switched capacitor circuit 2 has an equivalent resistance Rs corresponding to the frequency f of the inputted control signals CK1A an CK2B. Therefore, at the connection point A connecting the switched capacitor circuit 2 and the resistor element 3, a divided voltage V_{A} obtained by dividing the power source voltage AVDD by the equivalent resistance Rs of the switched capacitor circuit 2 and the resistance R of the resistor element 3 appears, and the divided voltage V_{A} is smoothened by the smoothing capacitor 4. When the divided voltage V_{A} is higher than the threshold voltage Vth of the Schmitt circuit 5 (see the voltage (1) in FIG. 3A), the Schmitt circuit 5 outputs a high-level signal H (see the signal (1) in FIG. 3B). On the other hand, when the divided voltage V_{A} is lower than the threshold voltage Vth of the Schmitt circuit 5 (see the voltage (2) in FIG. 3A), the Schmitt circuit 5 outputs a low-level signal L (see the signal (2) in FIG. 3B).

Thus, in the frequency detection circuit 10 according to this embodiment, when the frequency f of the input clock signal S is higher than a predetermined value, a high-level signal H is outputted. On the other hand, when the frequency f of the input clock signal S is lower than a predetermined value, a low-level signal L is outputted. Accordingly, with this frequency detection circuit 10, the frequency of the input clock signal S can be detected or discriminated.

In the meantime, in cases where the frequency f of the input clock signal S is near the threshold frequency, the divided voltage V_{A} appeared at the connection point A of the switched capacitor circuit 2 and the resistor element 3 fluctuates near the threshold voltage Vth since the divided voltage V_{A} is in a sawtooth wave pattern. In the case of a detection circuit using an inverter, the fluctuation of the divided voltage V_{A} causes fluctuation of the output signal. To solve this problem, in this embodiment, the aforementioned Schmitt circuit 5 is employed as a frequency detection circuit to prevent occurrence of instable operation near the threshold voltage Vth by the hysteresis characteristics.

When the threshold voltage Vtsh of the Schmitt circuit 5 is known, the threshold voltage Vtsh is represented by the following equation (1).

Vtsh=R×(Rs+R)×AVDD (1)

where R is the resistance of the resistor element 3, Rs is the equivalent resistance of the switched capacitor circuit 2, and AVDD is a power supply voltage.

Accordingly, the equivalent resistance Rs of the switched capacitor circuit 2 can be represented by the following equation (2) by transforming the equation (1) as follows.

Rs=(AVDD/Vtsh−1)×R (2)

The threshold frequency Ft of the Schmitt circuit 5 is represented by the following equation (3).

Ft=1/Rs×Cs (3)

where Cs is a capacitance of the switched capacitor circuit.

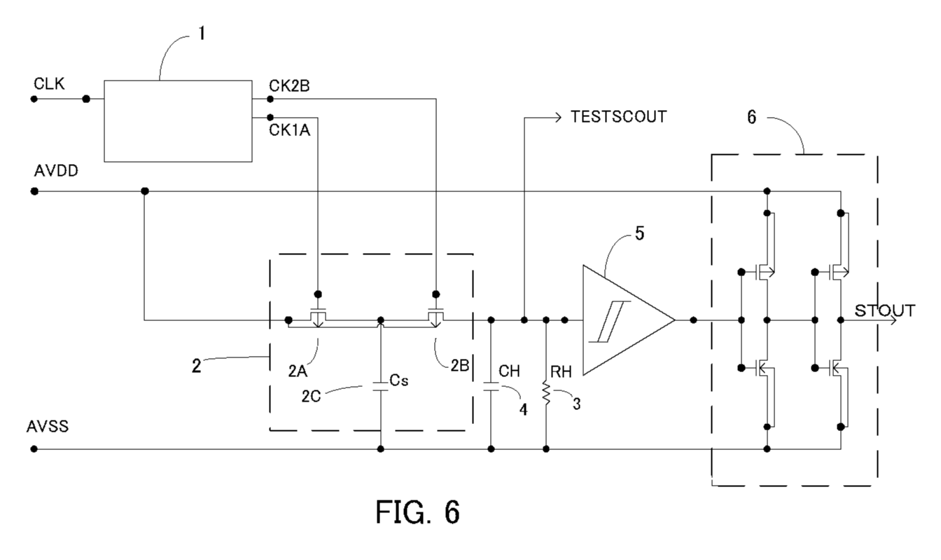

Now, a concrete example of the frequency detection circuit 10 according to this embodiment is shown in FIG. 6. In this circuit, the reference numeral “1” denotes a clock generator, “2” denotes a switched capacitor circuit, “3” denotes a resistor element, “4” denotes a smoothing capacitor, “5” denotes a Schmitt circuit, and “6” denotes a buffer circuit.

In this switched capacitor circuit 2, as shown in FIG. 6, a first MOS transistor 2A and a second MOS transistor 2B are connected in series, and one end of the capacitor Cs is connected to the connection point of the transistors 2A and 2B. The source terminal of the first MOS transistor 2A is connected to the power source terminal AVDD, and the other end of the capacitor Cs is connected to the ground terminal AVSS. On the other hand, a clock signal CLK having a predetermined frequency is inputted into the clock generator 1. This clock generator 1 is configured to output a first control signal CK1A and a second control signal CK2B which are reverse in phase and have non-overlap durations from the inputted clock signal CLK. The first control signal CK1A is inputted into the gate of the first MOS transistor 2A, and the second control signal CK2B is inputted into the gate of the second MOS transistor 2B. Thus, the first and second MOS transistors 2A and 2B are controlled by the first and second control signals CK1A and CK2B, respectively. Between the drain of the second MOS transistor 2B and the other end of the capacitor Cs or the ground terminal AVSS, a smoothing capacitor (CH) 4 is connected.

A resistor element (RH) 3 is connected to both ends of the smoothing capacitor (CH) 4. The resistance of the resistor element 3 and the equivalent resistance Rs of the switched capacitor circuit 2 divide the power source voltage AVDD. The divided power source voltage is inputted into the Schmitt circuit 5. To the output terminal of the Schmitt circuit 5, a known buffer circuit 6 is connected.

Thus, in this circuit, depending on the frequency of the input clock signal CLK inputted into the clock generator 1, the equivalent resistance Rs of the switched capacitor circuit 2 is decided. Therefore, the power source voltage AVDD is divided by the equivalent resistance Rs of the switched capacitor circuit 2 which is decided by the frequency of the input clock signal CLK and the resistance RH of the resistor element 3. The divided voltage is smoothened by the capacitor 4 and then inputted into the Schmitt circuit 5. In the Schmitt circuit 5, when the inputted divided voltage is higher than the predetermined threshold voltage, the circuit 5 outputs a high-level signal H, while when the inputted divided voltage is lower than the predetermined threshold voltage, the circuit 5 outputs a low-level signal L. Accordingly, with this circuit, although the structure is very simple, whether or not the frequency of the input clock signal CLK is higher or lower than the predetermined value can be detected easily and assuredly.

When the circuit of the aforementioned embodiment was operated at the power source voltage of 1.8 V, the operating current was about 25 μA, and therefore the consumption power was about 45 μW. It was confirmed that the power consumption could have greatly saved as compared with a conventionally available frequency detection circuit of the power source voltage: 12 V, the operating current: 3.5 mA, and the power consumption: 42 mW. It is also confirmed that the circuit occupancy area was reduced to less than 30% of that of the conventional one.

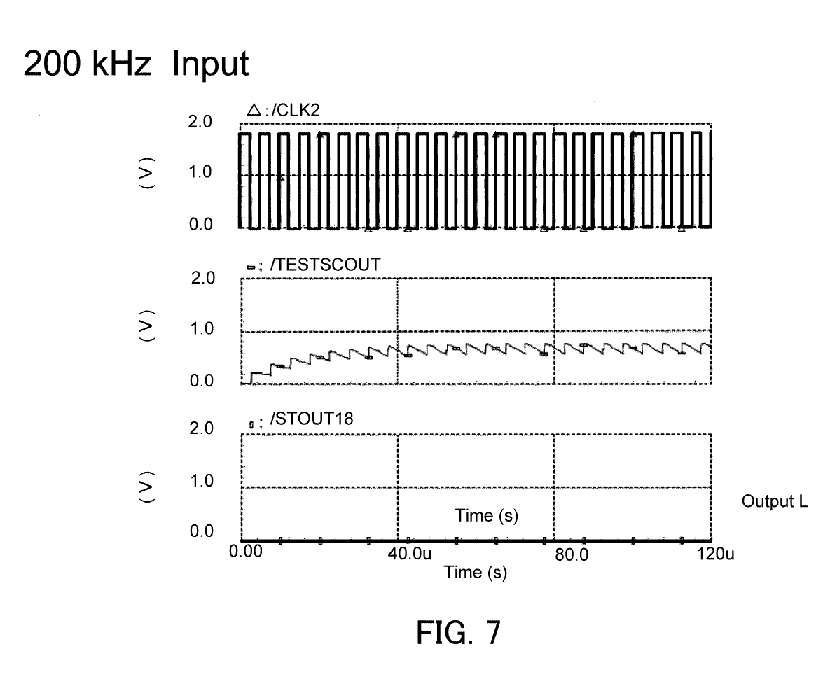

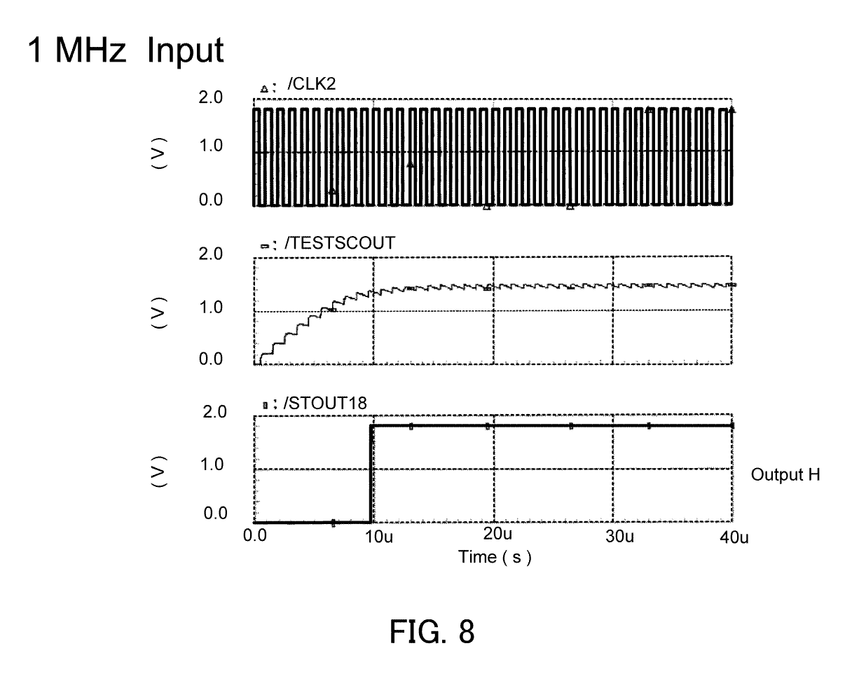

Next, in the circuit of the aforementioned embodiment, the wave pattern (wave pattern from the TESTSCOUT terminal) of the divided voltage and the wave pattern (wave pattern from the STOUT terminal) of the output voltage were investigated when the threshold frequency of the Schmitt circuit 5 was set to 470 kHz and the frequency of the input clock signal CLK was set to 200 kHz and 1 MHz. The results are shown in FIG. 7 and FIG. 8. In either frequency, the wave pattern of the divided voltage was in a saw-tooth pattern. However, in the case where the input clock signal CLK was 200 kHz, the output was about 0 V and became a constant low-level signal L. On the other hand, in the case where the input clock signal CLK was 1 MHz, the output was about 1.8 V and became a constant high-level signal H.

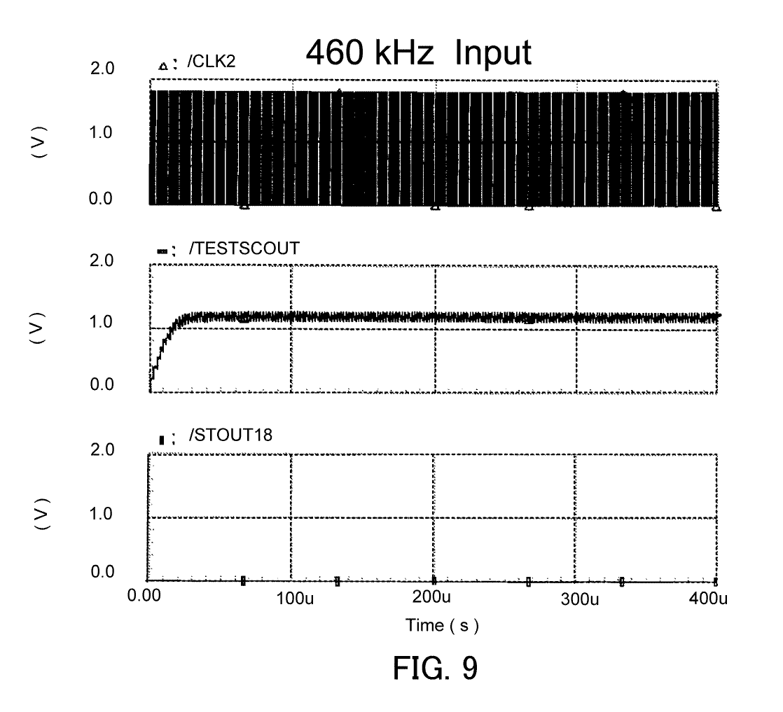

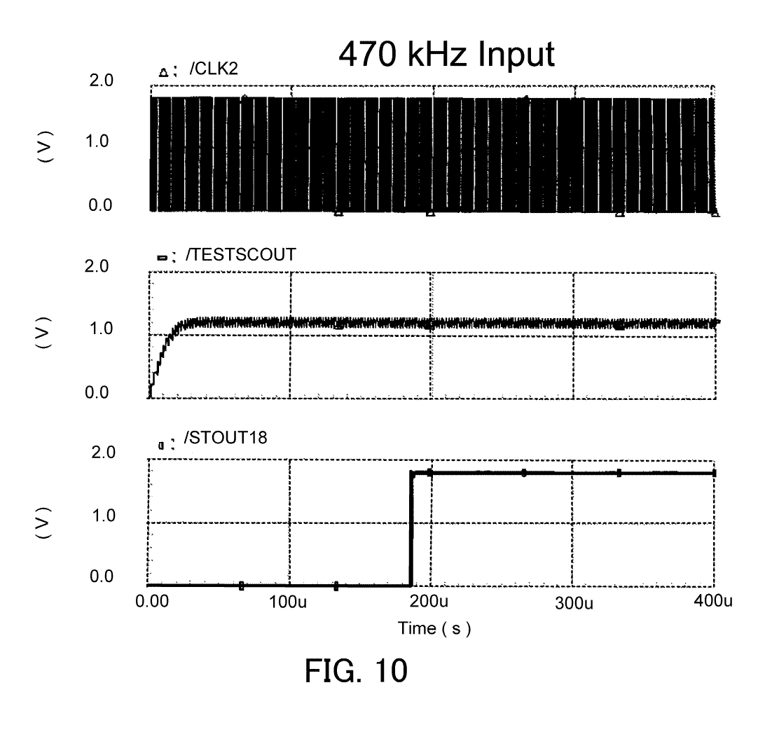

Furthermore, an experiment was performed to confirm the effects of the Schmitt circuit 5. As mentioned above, in the case of not using a Schmitt circuit, the output becomes unstable near the threshold frequency, resulting in fluctuation phenomena in which the output signal alternatively becomes a high-level H and a low-level L. The fluctuation phenomena can be solved by a Schmitt circuit. In the frequency detection circuit of the aforementioned embodiment, when the threshold frequency of the Schmitt circuit was 470 kHz, input clock signals CLK having a frequency of 460 kHz and 470 KHz were inputted to the frequency detection circuit, respectively, and the respective outputs were examined. The results are shown in FIG. 9 and FIG. 10. As will be apparent from the results, in the case where the input clock signal CLK was 460 kHz, the output was about 0 V and became a constant low-level signal L. In the case where the input clock signal CLK was 470 kHz, the output was about 1.8 V, and it was confirmed that the output became a constant high-level signal H and no fluctuation. Thus, in cases where the frequency of an input clock signal to be detected is near a threshold frequency, employment of a Schmitt circuit enables stable frequency detection.

### BROAD SCOPE OF THE INVENTION

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” is meant as an non-specific, general reference and may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

What is claimed is:

1. A frequency detection circuit, comprising:
a switched capacitor circuit having one end to which a power source voltage is applied, the switched capacitor circuit being configured to change its equivalent resistance depending on a frequency of an input clock signal;
a resistor element having one end to which the other end of the switched capacitor circuit is connected and the other end grounded; and
a divided voltage detection circuit configured to detect a divided voltage of the power source voltage divided by the switched capacitor circuit and the resistor element and output a high-level signal when the divided voltage is higher than a threshold voltage and a low-level signal when the divided voltage is lower than the threshold voltage.

2. The frequency detection circuit as recited in claim 1, wherein the divided voltage detection circuit is a Schmitt circuit.

3. The frequency detection circuit as recited in claim 1, further comprising a smoothing capacitor with one end connected to a connection point of the switched capacitor circuit and the resistor element and the other end grounded.

4. The frequency detection circuit as recited in claim 2, further comprising a smoothing capacitor with one end connected to a connection point of the switched capacitor circuit and the resistor element and the other end grounded.

5. The frequency detection circuit as recited in claim 1, further comprising a clock generator configured to input the input clock signal, create two kinds of control signals reverse in phase and having non-overlap durations from the input clock signal, and output the control signals to the switched capacitor circuit.

6. The frequency detection circuit as recited in claim 2, further comprising a clock generator configured to input the input clock signal, create two kinds of control signals reverse in phase and having non-overlap durations from the input clock signal, and output the control signals to the switched capacitor circuit.

7. The frequency detection circuit as recited in claim 3, further comprising a clock generator configured to input the input clock signal, create two kinds of control signals reverse in phase and having non-overlap durations from the input clock signal, and output the control signals to the switched capacitor circuit.

8. The frequency detection circuit as recited in claim 4, further comprising a clock generator configured to input the input clock signal, create two kinds of control signals reverse in phase and having non-overlap durations from the input clock signal, and output the control signals to the switched capacitor circuit.

9. The frequency detection circuit as recited in claim 5, wherein the switched capacitor circuit includes:
a first MOS transistor having a source terminal to which the power source voltage is applied and a gate terminal to which one of the two kinds of control signals is inputted;
a second MOS transistor having a source terminal to which a drain terminal of the first MOS transistor is connected and a gate terminal to which the other of the two kinds of control signals is inputted; and
a capacitor having one end to which a connection point of the drain terminal of the first MOS transistor and the source terminal of the second MOS transistor is connected and the other end grounded.

10. The frequency detection circuit as recited in claim 6, wherein the switched capacitor circuit includes:
a first MOS transistor having a source terminal to which the power source voltage is applied and a gate terminal to which one of the two kinds of control signals is inputted;
a second MOS transistor having a source terminal to which a drain terminal of the first MOS transistor is connected and a gate terminal to which the other of the two kinds of control signals is inputted; and
a capacitor having one end to which a connection point of the drain terminal of the first MOS transistor and the source terminal of the second MOS transistor is connected and the other end grounded.

11. The frequency detection circuit as recited in claim 7 wherein the switched capacitor circuit includes:
a first MOS transistor having a source terminal to which the power source voltage is applied and a gate terminal to which one of the two kinds of control signals is inputted;
a second MOS transistor having a source terminal to which a drain terminal of the first MOS transistor is connected and a gate terminal to which the other of the two kinds of control signals is inputted; and
a capacitor having one end to which a connection point of the drain terminal of the first MOS transistor and the source terminal of the second MOS transistor is connected and the other end grounded.

12. The frequency detection circuit as recited in claim 8, wherein the switched capacitor circuit includes:
a first MOS transistor having a source terminal to which the power source voltage is applied and a gate terminal to which one of the two kinds of clock signals is inputted;
a second MOS transistor having a source terminal to which a drain terminal of the first MOS transistor is connected and a gate terminal to which the other of the two kinds of clock signals is inputted; and
a capacitor having one end to which a connection point of the drain terminal of the first MOS transistor and the source terminal of the second MOS transistor is connected and the other end grounded.

13. A frequency detection circuit, comprising:
a switched capacitor circuit unit including a switched capacitor circuit, wherein the switched capacitor circuit is configured to change its equivalent resistance depending on a frequency of an input clock signal inputted to the switched capacitor circuit unit;
a resistor element connected between the switched capacitor circuit and a ground terminal so as to divide a reference voltage by the equivalent resistance of the switched capacitor circuit and a resistance of the resistor element;
a smoothing capacitor connected to the resistor element in parallel; and
a Schmitt circuit configured to input a divided voltage of the reference voltage divided by the equivalent resistance of the switched capacitor circuit and the resistance of the resistor element and output a high-level signal or a low-level signal depending on the inputted divided voltage, whereby the Schmitt circuit outputs the high-level signal when the frequency of the input clock signal is higher than a predetermined threshold frequency and outputs the low-level signal when the frequency of the input clock signal is lower than a predetermined threshold frequency.

14. The frequency detection circuit as recited in claim 13, wherein the switched capacitor circuit unit includes:
a clock generator configured to input the input clock signal and create two kinds of control signals reverse in phase; and
the switched capacitor circuit which is controlled so that the equivalent resistance changes depending on the frequency of the input clock signal.

15. The frequency detection circuit as recited in claim 14, wherein the switched capacitor circuit includes:
a first MOS transistor having a source terminal to which the reference voltage is applied and a gate terminal to which one of the two kinds of control signals is inputted;
a second MOS transistor having a source terminal to which a drain terminal of the first MOS transistor is connected and a gate terminal to which the other of the two kinds of control signals is inputted;
a capacitor having one end to which a connection point of the drain terminal of the first MOS transistor and the source terminal of the second MOS transistor is connected and the other end grounded.
